(19) United States
(12) Patent Application Publication
(10) Pub. No.: US 2024/0087856 A1
(43) Pub. Date: Mar. 14, 2024

(54) SUBSTRATE TREATING APPARATUS AND SUBSTRATE TREATING METHOD USING THE SAME

(71) Applicant: Samsung Electronics Co., Ltd., Suwon-si (KR)

(72) Inventors: Jiwon Son, Suwon-si (KR); Sunggil Kang, Suwon-si (KR); Kangmin Do, Suwon-si (KR); Youngsun Kim, Suwon-si (KR); Younghoo Kim, Suwon-si (KR); Sangjin An, Suwon-si (KR)

(21) Appl. No.: 18/447,479

(22) Filed: Aug. 10, 2023

(30) Foreign Application Priority Data
Sep. 8, 2022 (KR) 10-2022-0114463

(51) Int. Cl. H01J 37/32; C23C 16/455

(52) U.S. Cl. CPC H01J 37/32715; C23C 16/45565; H01J 37/32082; H01J 37/32477; H01J 37/32633; H01J 2237/3321; H01J 2237/334

(57) ABSTRACT

A substrate treating apparatus includes a process chamber configured to perform plasma treatment, a substrate support in a lower portion of the process chamber and configured to support a substrate, a showerhead in an upper portion of the process chamber and configured to supply a process gas for the plasma treatment toward the substrate, and a baffle surrounding the substrate support. The substrate support functions as a first electrode for generating plasma, the showerhead and the baffle function as a second electrode for generating the plasma, the baffle has a variable height, and an area of the second electrode varies as a height of the baffle varies.

### CROSS-REFERENCE TO RELATED APPLICATION

This application is based on and claims priority under 35 U.S.C. § 119 to Korean Patent Application No. 10-2022-0114463, filed on Sep. 8, 2022, in the Korean Intellectual Property Office, the disclosure of which is incorporated by reference herein in its entirety.

### BACKGROUND

The inventive concept relates to a substrate treating apparatus and a substrate treating method using the same. More specifically, the inventive concept relates to a substrate treating apparatus, which includes a baffle configured to move vertically, and a substrate treating method using the same.

Recently, as semiconductor elements become miniaturized and highly integrated, a critical dimension (CD) of a pattern of a semiconductor element gradually decreases, but an aspect ratio of the pattern gradually increases. Accordingly, the process difficulty of plasma etching for forming the pattern of the semiconductor element is gradually increasing. In order to obtain the pattern having a high aspect ratio while overcoming the increase in process difficulty, a method is proposed in which a process of depositing a sacrificial layer on a substrate and etching the substrate using the sacrificial layer is repeatedly performed.

### SUMMARY

The inventive concept provides a substrate treating apparatus and a substrate treating method using the same. In the substrate treating apparatus, the profile of a sacrificial layer deposited on a patterned structure formed on a substrate is adjusted by varying the height of a baffle that functions as an electrode. Accordingly, the reliability of an etching process using the sacrificial layer is improved, and the quality and yield of semiconductor elements manufactured through the etching process may be enhanced.

According to an aspect of the inventive concept, there is provided a substrate treating apparatus which includes a process chamber configured to perform plasma treatment in a treatment space, a substrate support in a lower portion of the process chamber and configured to support a substrate, a showerhead in an upper portion of the process chamber and configured to supply a process gas for the plasma treatment toward the substrate, and a baffle surrounding the substrate support. The substrate support functions as a first electrode for generating plasma, the showerhead and the baffle function as a second electrode for generating the plasma, the baffle has a variable height, and an area of the second electrode in contact with the treatment space varies as a height of the baffle varies.

According to another aspect of the inventive concept, there is provided a substrate treating method which includes positioning a substrate having a patterned structure on a substrate support inside a process chamber, performing first adjustment for adjusting a height of a baffle inside the process chamber, depositing a sacrificial layer on the patterned structure, performing second adjustment for adjusting the height of the baffle, and etching the substrate using the sacrificial layer. The substrate support functions as a first electrode for generating plasma, the baffle functions as a second electrode for generating the plasma, and an area of the second electrode varies as the height of the baffle varies.

According to another aspect of the inventive concept, there is provided a substrate treating apparatus which includes a process chamber configured to perform plasma treatment in a treatment space, a substrate support in a lower portion of the process chamber and configured to support a substrate, a showerhead in an upper portion of the process chamber and configured to supply a process gas for the plasma treatment toward the substrate, a liner on side walls of the process chamber and configured to protect the side walls of the process chamber, and a baffle surrounding the substrate support. The substrate support functions as a first electrode, to which radio-frequency (RF) power having a frequency of 13.56 Mhz is applied, to generate plasma, the showerhead, the baffle, and the liner function as a second electrode, which includes a ground electrode, to generate the plasma, the baffle has a variable height, an area of the second electrode in contact with the treatment space varies as a height of the baffle varies.

### BRIEF DESCRIPTION OF THE DRAWINGS

Embodiments will be more clearly understood from the following detailed description taken in conjunction with the accompanying drawings in which:

FIG. 1 is a cross-sectional view showing a substrate treating apparatus according to an embodiment;

FIGS. 2A and 2B are views showing plasma regions and sheath regions according to the positions of a baffle;

FIG. 3 is a view showing sacrificial layers deposited on patterns according to the positions of the baffle;

FIG. 4 is a view showing TEM images and ratios of the vertical lengths and the horizontal lengths of the sacrificial layers deposited on the patterns according to the positions of the baffle;

FIG. 5 is a cross-sectional view showing patterns after etching according to the positions of the baffle;

FIG. 6 is a flowchart showing a substrate treating method according to an embodiment; and

FIGS. 7A to 7E are cross-sectional views showing respective operations of the substrate treating method according to an embodiment.

### DETAILED DESCRIPTION

Hereinafter, embodiments of the inventive concept will be described in detail with reference to the accompanying drawings. The same reference numerals are used for the same elements in the drawings, and redundant description thereof may be omitted in the interest of brevity.

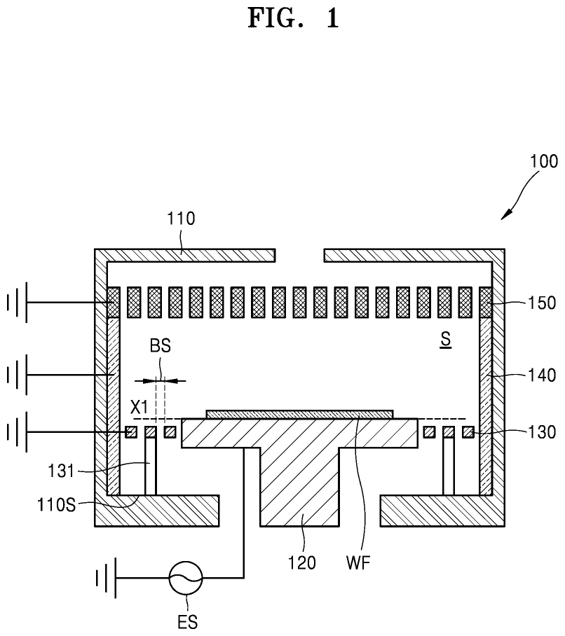

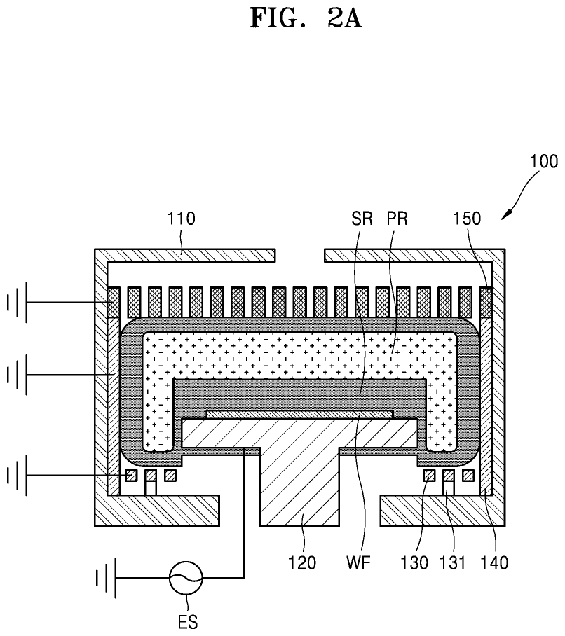

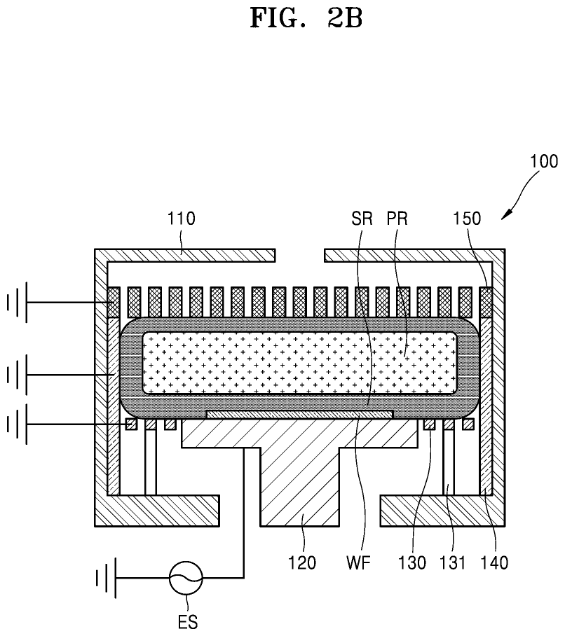

FIG. 1 is a cross-sectional view showing a substrate treating apparatus 100 according to an embodiment. FIGS. 2A and 2B are views showing plasma regions PR and sheath regions SR according to the positions of a baffle 130. Specifically, FIG. 2A is a view showing a plasma region PR and a sheath region SR which are formed when the height of the baffle 130 is lower than the height of a substrate WF, and FIG. 2B is a view showing a plasma region PR and a sheath region SR which are formed when the height of the baffle 130 is substantially the same as the height of the substrate WF.

Referring to FIGS. 1, 2A, and 2B, the substrate treating apparatus 100 may include a process chamber 110, a substrate support 120, a baffle 130, a liner 140, and a showerhead 150.

The substrate treating apparatus 100 may be configured to perform treatment of the substrate WF by using plasma. The substrate treating apparatus 100 may be configured to perform, for example, plasma etching or plasma-enhanced chemical vapor deposition. The substrate treating apparatus 100 may be configured to perform, for example, both the plasma etching and the plasma-enhanced chemical vapor deposition.

The substrate WF may include a group IV semiconductor such as silicon (Si) or germanium (Ge), a group IV-IV compound semiconductor such as silicon-germanium (SiGe) or silicon carbide (SiC), or a group III-V compound semiconductor such as gallium arsenide (GaAs), indium arsenide (InAs), or indium phosphide (InP). In an embodiment, the substrate WF may have a silicon on insulator (SOI) structure. In an embodiment, the substrate WF may have a buried oxide layer. The substrate WF may include a conductive region, for example, wells doped with impurities. The substrate WF may have various element separation structures such as a shallow trench isolation (STI) structure that separates the doped wells from each other.

The process chamber 110 may include, for example, metal such as aluminum. The process chamber 110 may have, for example, a cylindrical shape. The process chamber 110 may provide a treatment space S in which the substrate WF is treated by using the plasma. The process chamber 110 may isolate the treatment space S from the outside, and thus process parameters such as pressure, temperature, and plasma density may be controlled.

The process chamber 110 may provide the plasma region PR and the sheath region SR that surrounds the plasma region PR. Specifically, the plasma region PR is provided within a certain radius from the center of the process chamber 110. The sheath region SR horizontally surrounds the plasma region PR, and may be provided between the plasma region PR and the baffle 130, between the plasma region PR and the liner 140, and between the plasma region PR and the showerhead 150. Here, the plasma region PR is a space in which plasma is generated, and the sheath region SR is a space which is affected by the plasma.

The process chamber 110 may be connected to a gas supply device for supplying a process gas. The process gas may include, for example, a deposition gas or an etching gas. In addition, the process chamber 110 may further include an exhaust device for discharging reactants, debris, process gas, and plasma after the substrate WF is treated. The gas supply device may include a valve that opens and closes a flow path in the gas supply device. The exhaust device may include a pump that maintains the internal pressure of the process chamber 110 at a process pressure and a valve that opens and closes a flow path in the exhaust device.

The substrate support 120 may be configured to support the substrate WF. The substrate support 120 may have, for example, a disc shape. The substrate support 120 may be configured to support the substrate WF by using, for example, electrostatic force. The substrate support 120 may include, for example, a ceramic material such as aluminum nitride (AlN) or a metal material such as aluminum or a nickel-based alloy. The substrate support 120 may further include a heater for controlling the temperature of the substrate WF. The heater may maintain the temperature of the substrate WF at a certain temperature while the substrate WF is treated. In an embodiment, the substrate support 120 may function as a first electrode for generating plasma in the process chamber 110.

A first power generator ES may apply source power for generating plasma to the substrate support 120. In an embodiment, the source power may include radio-frequency (RF) power. In an embodiment, the frequency of the RF power may include a frequency selected in a range of about 1 Mhz to about 60 Mhz. For example, the frequency of the RF power may be 13.56 Mhz. In an embodiment, a plurality of source powers having different frequencies may be applied to the substrate support 120. In an embodiment, each of the plurality of source powers may include RF power. In an embodiment, the different frequencies of the plurality of source powers may be frequencies selected in the range of about 1 Mhz to about 60 Mhz.

Also, bias power may be applied to the substrate support 120. The bias power may be power for controlling ion energy of the generated plasma.

The baffle 130 may surround the substrate support 120. Specifically, the baffle 130 may be located between the outside of the substrate support 120 and the inner wall of the process chamber 110, and may surround the substrate support 120. The baffle 130 may include a plurality of slits or openings BS that pass through the baffle 130 in a vertical direction (Z direction). In this case, the baffle 130 may have a disc shape having the plurality of slits BS. Specifically, the baffle 130 may have a disk shape having the plurality of slits BS that pass through the baffle 130 in the vertical direction (Z direction) and have a horse hoof shape on the X-Y plane. The baffle 130 may include, for example, metal such as aluminum. In an embodiment, the baffle 130 may function as a second electrode for generating plasma in the process chamber 110. In this case, the area of the baffle 130 may be referred to as the area of the second electrode. Here, the area of the baffle 130 represents the area of the upper surface of the baffle 130 that is in contact with the treatment space S.

The baffle 130 may adjust the flow rate of the process gas in the treatment space S. The baffle 130 may discharge the process gas or the like in the treatment space S from the treatment space S via the plurality of slits BS.

In an embodiment, the baffle 130 may have a variable height. Specifically, the baffle 130 may be raised and lowered in the vertical direction (Z direction). In an embodiment, the greatest or maximum height of the baffle 130 may be substantially the same as the height of the substrate WF. Specifically, the height of the upper surface of the baffle 130 may be substantially the same as the height of the lower surface of the substrate WF (i.e., the height of the upper surface of the substrate support 120 or X1 in FIG. 1). In an embodiment, the substrate treating apparatus 100 may include a raising/lowering device or height adjustment device 131 configured to raise and lower the baffle 130 in the vertical direction (Z direction). Here, the baffle 130 may be vertically moved from the lower surface of the substrate WF to a lower surface 1105 of the process chamber 110 by the raising/lowering device 131. As the height of the baffle 130 varies, the straightness of plasma ions may vary. Specifically, when the height of the baffle 130 functioning as the second electrode is lower than the height of the substrate WF, the area of the second electrode is greater than that when the height of the baffle 130 is substantially the same as the height of the substrate WF (e.g., Here, the area of the first electrode (i.e., the area of the substrate support 120) is not variable. Accordingly, as the area of the second electrode increases, a ratio between the area of the second electrode and the area of the first electrode also increases, and thus, the size of the plasma region PR and the size of the sheath region SR are adjusted. Accordingly, the absolute value of self-bias voltage increases, and the straightness of plasma ions increases. On the other hand, when the height of the baffle 130 functioning as the second electrode is the substantially the same as the height of the substrate WF, the area of the second electrode is less than that when the height of the baffle 130 is lower than the height of the substrate WF. Here, the area of the first electrode (i.e., the area of the substrate support 120) is not variable as described above. Accordingly, as the area of the second electrode decreases, a ratio between the area of the second electrode and the area of the first electrode also decreases, and thus, the size of the plasma region PR and the size of the sheath region SR are adjusted. Accordingly, the absolute value of self-bias voltage decreases, and the straightness of plasma ions decreases. The treatment of the substrate WF such as plasma etching or plasma-enhanced chemical vapor deposition may be controlled by adjusting the straightness of plasma ions.

The liner 140 may be located on the inner wall of the process chamber 110. The liner 140 may prevent the inner wall of the process chamber 110 from being damaged by plasma. The liner 140 may include, for example, metal such as aluminum. In an embodiment, the liner 140 may function as the second electrode together with the baffle 130. In this case, the area of the baffle 130 and the area of the liner 140 may be referred to as the area of the second electrode. Here, the area of the baffle 130 represents the area of the upper surface of the baffle 130 that is in contact with the treatment space S, and the area of the liner 140 represents the area of the side surface of the liner 140 that is in contact with the treatment space S. In an embodiment, when the height of the baffle 130 is lower than the height of the substrate WF (FIG. 2A), the area of the liner 140 in contact with the treatment space S is greater than that when the height of the baffle 130 is substantially the same as the height of the substrate WF (FIG. 2B). In an embodiment, the liner 140 may include a ground electrode.

The showerhead 150 may be located in an upper portion of the process chamber 110. The showerhead 150 may face the substrate support 120. The showerhead 150 may uniformly distribute, to the upper region of the substrate support 120, the process gas supplied into the process chamber 110 from a gas supply device. In an embodiment, the showerhead 150 may function as the second electrode together with the baffle 130. In this case, the area of the baffle 130 and the area of the showerhead 150 may be referred to as the area of the second electrode. Here, the area of the baffle 130 represents the area of the upper surface of the baffle 130 that is in contact with the treatment space S, and the area of the showerhead 150 represents the area of the lower surface of the showerhead 150 that is in contact with the treatment space S. In an embodiment, the showerhead 150 may include a ground electrode.

In an embodiment, the baffle 130, the liner 140, and the showerhead 150 may function as the second electrode. In this case, the area of the baffle 130, the area of the liner 140, and the area of the showerhead 150 may be referred to as the area of the second electrode. Here, the area of the baffle 130 represents the area of the upper surface of the baffle 130 that is in contact with the treatment space S, the area of the liner 140 represents the area of the side surface of the liner 140 that is in contact with the treatment space S, and the area of the showerhead 150 represents the area of the lower surface of the showerhead 150 that is in contact with the treatment space S.

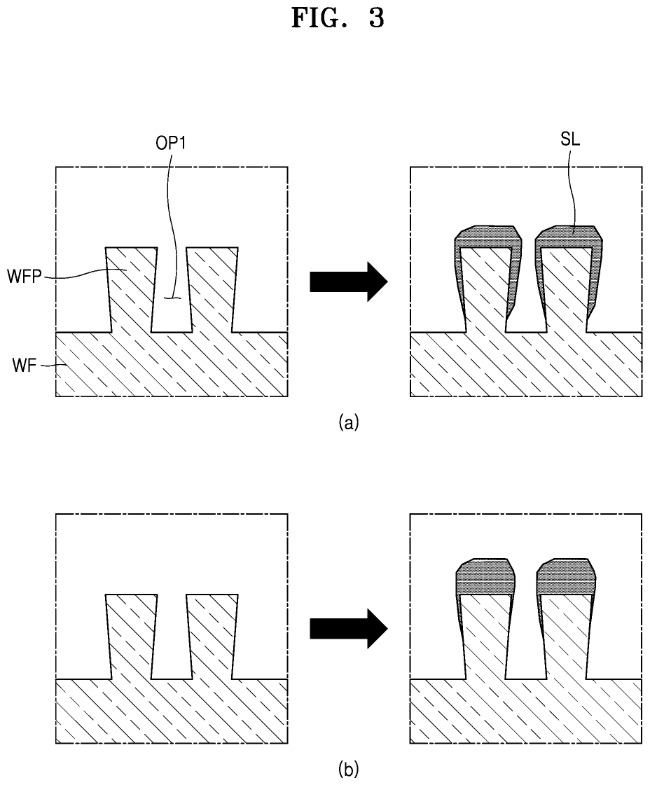

The substrate treating apparatus 100 according to an embodiment includes the baffle 130 having a variable height. As the height of the baffle 130 functioning as the second electrode varies, the area of the second electrode varies. Accordingly, the ratio between the area of the second electrode and the area of the first electrode varies, and the plasma region PR and the sheath region SR are adjusted. As a result, the straightness of ions may vary. Through this, when a sacrificial layer SL (see FIG. 3) is deposited on a patterned structure WFP (see FIG. 3) formed on the substrate WF in the process chamber 110, the profile of the sacrificial layer SL may be adjusted. Accordingly, even when the critical dimension of the patterned structure WFP is small, it is possible to prevent clogging of an opening OP1 (see FIG. 3) between neighboring patterned structures WFP due to the sacrificial layer SL. Accordingly, after the sacrificial layer SL is deposited, the reliability of an etching process performed using the sacrificial layer SL may be improved. In addition, the quality and yield of semiconductor elements manufactured through the etching process may be enhanced. Hereinafter, deposition of the sacrificial layer SL and etching using the sacrificial layer SL according to the varying height of the baffle 130 will be described in detail with reference to FIGS. 3, 4, and 5.

FIG. 3 is a view showing before and after a deposition process according to a variable height of the baffle 130. Specifically, portion (a) of FIG. 3 shows profiles of the sacrificial layer SL before the sacrificial layer SL is deposited and after the sacrificial layer SL is deposited, when the height of the baffle 130 is lower than the height of the substrate WF. Portion (b) of FIG. 3 shows profiles of the sacrificial layer SL before the sacrificial layer SL is deposited and after the sacrificial layer SL is deposited, when the height of the baffle 130 is the substantially the same as the height of the substrate WF.

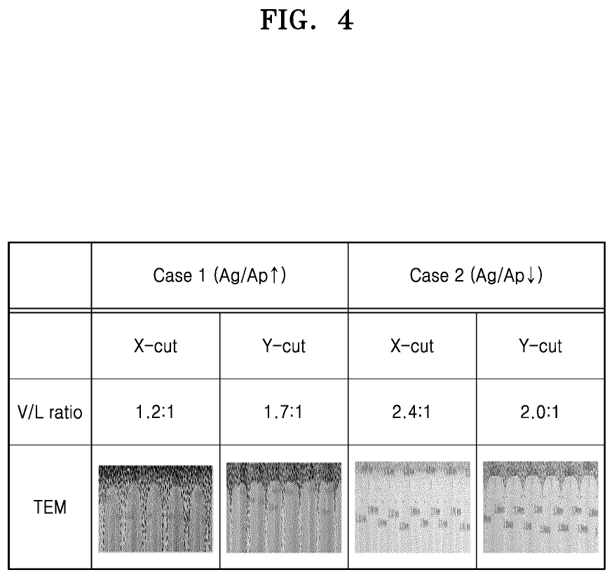

Referring to FIG. 3, in the case where the sacrificial layer SL is deposited when the vertical height of the baffle 130 is lower than the vertical height of the substrate WF, the straightness of plasma ions increases as described above with reference to FIGS. 1 to 2B. Therefore, the sacrificial layer SL is deposited relatively in the horizontal direction on the patterned structure WFP formed on the substrate WF. On the other hand, in the case where the sacrificial layer SL is deposited when the vertical height of the baffle 130 is substantially the same as the vertical height of the substrate WF, the straightness of plasma ions decreases as described above with reference to FIGS. 1 to 2B. Therefore, the sacrificial layer SL is deposited relatively in the vertical direction on the patterned structure WFP formed on the substrate WF. That is, referring to FIG. 3, the profile of the sacrificial layer SL formed on the patterned structure WFP may be adjusted according to process conditions by varying the vertical height of the baffle 130. Hereinafter, the deposition profile of the sacrificial layer SL illustrated in FIG. 3 will be described in more detail with reference to FIG. 4.

FIG. 4 is a view showing transmission electron microscope (TEM) images and V/L ratios of deposition profiles of sacrificial layers SL according to a variable height of the baffle 130. In FIG. 4, the V/L ratio refers to a value obtained by dividing the vertical length of the sacrificial layer SL (length in the Z direction) by the first horizontal length (length in the X direction) or the second horizontal length (length in the Y direction). Also, X-cut refers to a cross-section taken along a plane perpendicular to the first horizontal direction (X direction), and Y-cut refers to a cross-section taken along a plane perpendicular to the second horizontal direction (Y direction). Also, in FIG. 4, Case 1 shows that the sacrificial layer SL is deposited when the height of the baffle 130 is lower than the height of the substrate WF as in portion (a) of FIG. 3, and Case 2 shows that the sacrificial layer SL is deposited when the height of the baffle 130 is substantially the same as the height of the substrate WF as shown in portion (b) of FIG. 3.

Referring to FIG. 4, it may be confirmed that the V/L ratio value in Case 1 is smaller than the V/L ratio value in Case 2. That is, referring to FIG. 4, it may be confirmed that the sacrificial layer SL is deposited relatively in the horizontal direction on the patterned structure WFP when the height of the baffle 130 is lower than the height of the substrate WF, and it may be confirmed that the sacrificial layer SL is deposited relatively in the vertical direction on the patterned structure WFP when the height of the baffle 130 is substantially the same as the height of the substrate WF.

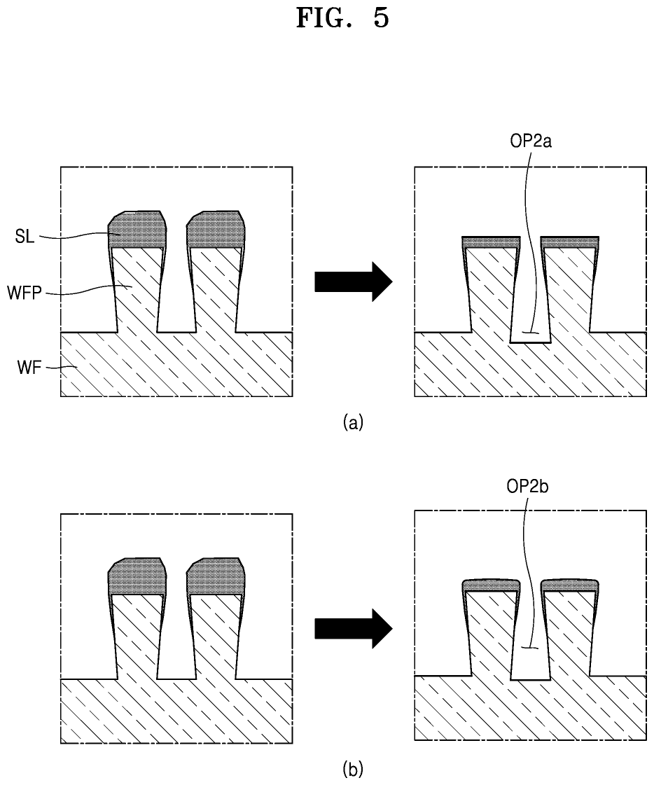

FIG. 5 is a view showing before and after an etching process according to a variable height of the baffle 130. Specifically, portion (a) of FIG. 5 is a view showing before and after the etching process, when the height of the baffle 130 is lower than the height of the substrate WF. Portion (b) of FIG. 5 is a view showing before and after the etching process, when the height of the baffle 130 is substantially the same as the height of the substrate WF. For convenience of description, the states before and after the etching process are illustrated in FIG. 5 on the basis of when the sacrificial layer SL is deposited relatively in the vertical direction (Z direction) on the patterned structure WFP as shown in portion (b) of FIG. 3. However, the profile of the sacrificial layer SL prior to performing the etching process is not limited thereto.

Referring to FIG. 5, in the case where the etching process is performed by using the deposited sacrificial layer SL when the vertical height of the baffle 130 is lower than the vertical height of the substrate WF, the straightness of plasma ions increases as described above with reference to FIGS. 1 and 2A. Therefore, the substrate WF is etched relatively in the vertical direction (Z direction). Therefore, an opening OP2a between neighboring patterned structures WFP is etched more deeply in the vertical direction (Z direction) than is an opening OP2b which will be described below, and both edges of the sacrificial layer SL formed on the patterned structures WFP are etched sharply. On the other hand, in the case where the etching process is performed by using the deposited sacrificial layer SL when the vertical height of the baffle 130 is substantially the same as the vertical height of the substrate WF, the straightness of plasma ions decreases as described above with reference to FIGS. 1 and 2B. Therefore, the substrate WF is etched relatively in the horizontal direction. Therefore, an opening OP2b between neighboring patterned structures WFP is etched more shallowly in the vertical direction (Z direction) than is the opening OP2a which has been described above, and both edges of the sacrificial layer SL formed on the patterned structures WFP are etched to be rounded. Referring to FIG. 5, the etching process of the substrate WF using the sacrificial layer SL is precisely controlled by adjusting the height of the baffle 130. Accordingly, a more delicate pattern may be formed on the substrate WF.

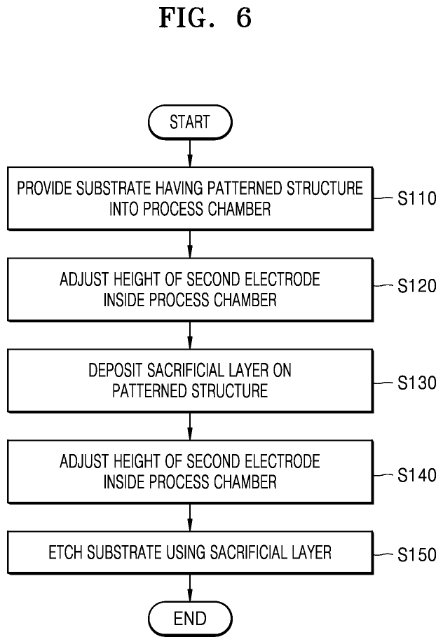

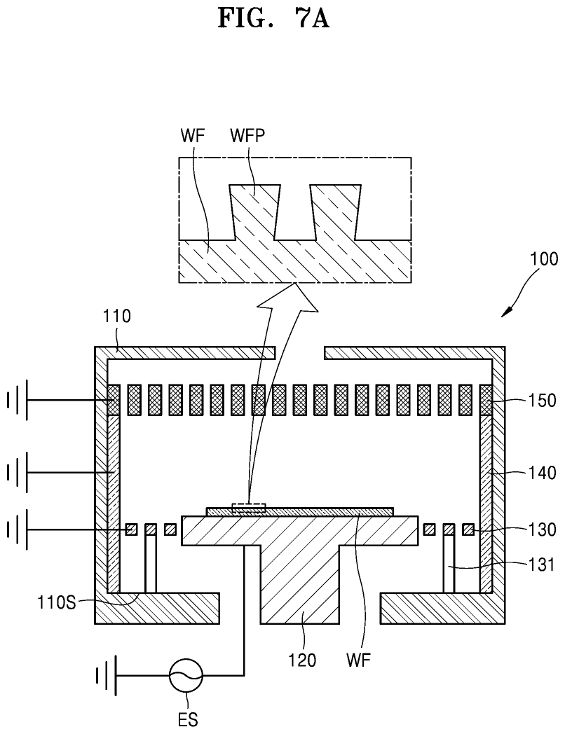

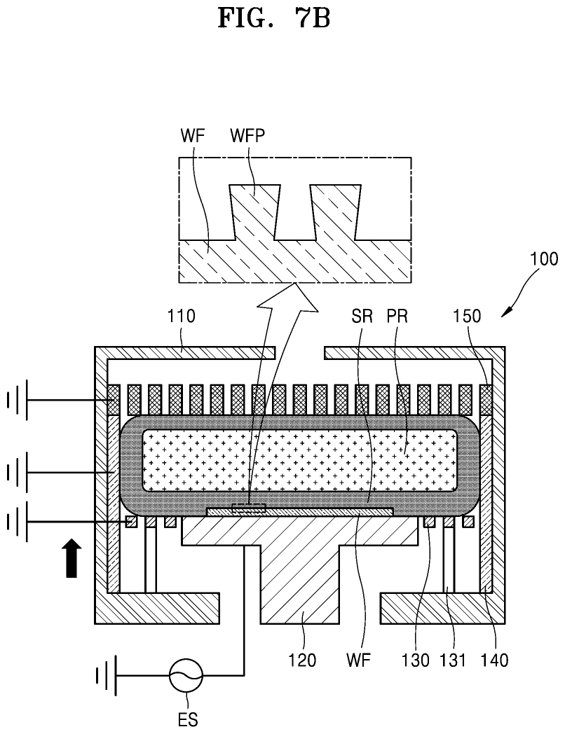

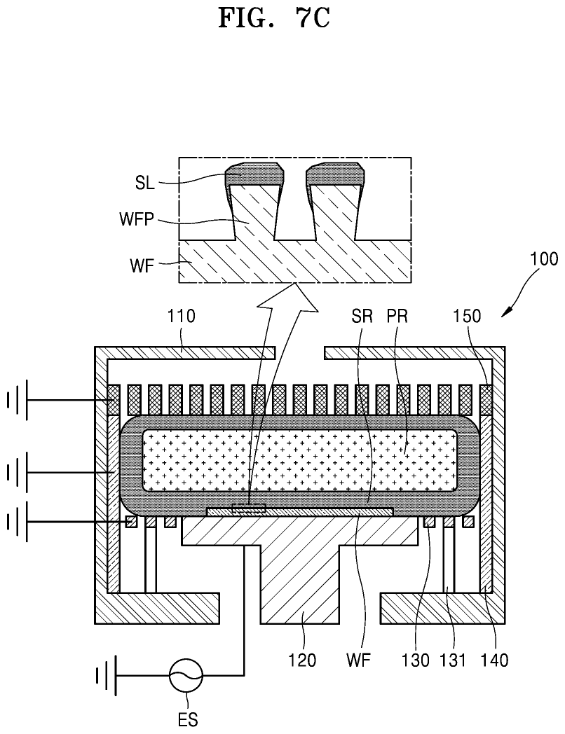

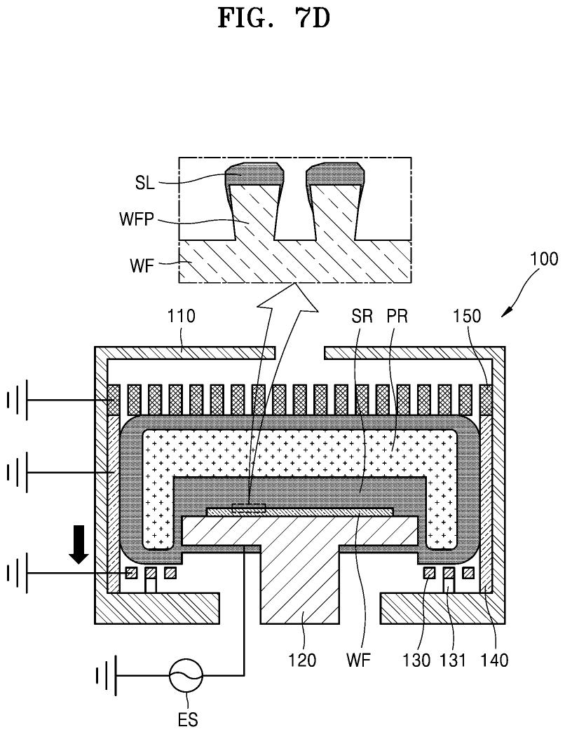

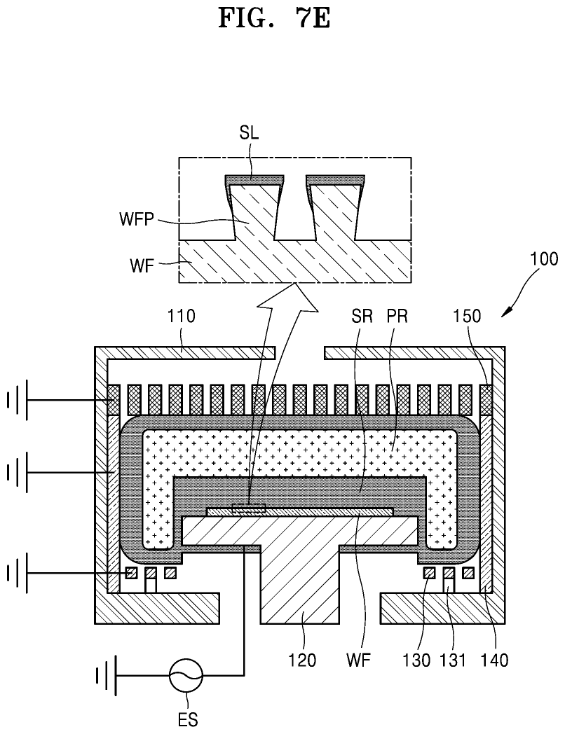

FIG. 6 is a flowchart showing a substrate treating method according to an embodiment. FIGS. 7A to 7E are cross-sectional views showing respective operations of the substrate treating method according to an embodiment.

Referring to FIGS. 6 and 7A, a substrate WF on which a patterned structure WFP is formed may be provided into a process chamber 110 (S110). The patterned structure WFP may be formed by etching the substrate WF using an etching mask. In an embodiment, the process of forming the patterned structure WFP may be performed before operation S110 is performed on the substrate WF. However, the inventive concept is not limited thereto. The substrate WF on which the patterned structure WFP is not formed may be provided into the process chamber 110, and the patterned structure WFP may be formed before a first process gas which will be described below is supplied. After operation S110 is performed, the first process gas may be supplied into the process chamber 110 by a gas supply device. The first process gas may be used to perform deposition. The first process gas may include a carrier gas and a deposition gas. The carrier gas may include, for example, Ar, He, etc. The deposition gas may include, for example, SiH₄, CH₄, etc., but the inventive concept is not limited thereto.

Referring to FIGS. 6 and 7B, after the first process gas is supplied into the process chamber 110, the height of a baffle 130 may be adjusted (S120). For example, as indicated by an arrow in FIG. 7B, the height of the baffle 130 may be varied to be substantially the same as the height of the substrate WF. However, the inventive concept is not limited thereto. In order to adjust the profile of a sacrificial layer SL according to process conditions, the height of the baffle 130 may be varied to be lower than the height of the substrate WF unlike FIG. 7B. After operation S120 is performed, a first power generator ES applies source power onto a substrate support 120 that functions as a first electrode. Subsequently, first plasma may be generated from the first process gas. In an embodiment, the source power may include RF power. Here, the frequency of the RF power may include a frequency selected in a range of about 1 Mhz to about 60 Mhz. In an embodiment, the first plasma may include capacitively coupled plasma (CCP).

Referring to FIGS. 6 and 7C, after the first plasma is generated, the sacrificial layer SL may be deposited on the patterned structure WFP using the first plasma (S130). Here, when the height of the baffle 130 is substantially the same as the height of the substrate WF, the sacrificial layer SL may be deposited relatively in the vertical direction on the patterned structure WFP. On the other hand, unlike that illustrated in FIG. 7C, when the height of the baffle 130 is lower than the height of the substrate WF, the sacrificial layer SL may be deposited relatively in the horizontal direction on the patterned structure WFP. After operation S130 is performed, the first plasma, reactants, debris, and the first process gas may be discharged from the process chamber 110 via an exhaust device. Next, a second process gas may be supplied into the process chamber 110 by a gas supply device. The second process gas may be used to perform etching. The second process gas may include a carrier gas and an etching gas. The carrier gas may include, for example, Ar, He, etc. The etching gas may include, for example, NF₃, CF₄, etc., but the inventive concept is not limited thereto.

Referring to FIGS. 6 and 7D, after the second process gas is supplied, the height of the baffle 130 may be adjusted (S140). For example, as indicated by an arrow in FIG. 7D, the height of the baffle 130 may be varied to be lower than the height of the substrate WF. However, the inventive concept is not limited thereto. In order to adjust the etching process according to process conditions, the height of the baffle 130 may be varied to be substantially the same as the height of the substrate WF unlike FIG. 7D. After operation S140 is performed, the first power generator ES applies source power onto the substrate support 120. Subsequently, second plasma may be generated from the second process gas. The source power may include RF power. Here, the frequency of the RF power may include a frequency selected in a range of about 1 Mhz to about 60 Mhz. In an embodiment, the second plasma may include capacitively coupled plasma (CCP).

Referring to FIGS. 6 and 7E, after the second plasma is generated, the substrate WF may be etched using the second plasma (S150). Here, when the height of the baffle 130 is lower than the height of the substrate WF, the substrate WF is etched relatively in the vertical direction (Z direction), and both edges of the sacrificial layer SL formed on the patterned structure WFP may be etched sharply. On the other hand, unlike that illustrated in FIG. 7E, when the height of the baffle 130 is substantially the same as the height of the substrate WF, the substrate WF is etched relatively in the horizontal direction (X direction), and both edges of the sacrificial layer SL formed on the patterned structure WFP may be etched to be rounded. After operation S150 is performed, the second plasma, reactants, debris, and the second process gas may be discharged from the process chamber 110 via an exhaust device.

In an embodiment, operations S120 to S150 may be performed a plurality of times. Specifically, operations S120 to S150 may be performed a plurality of times until a desired pattern is formed on the substrate WF. In an embodiment, when operations S120 to S150 are performed a plurality of times, the heights of the baffle 130 in operations S120 performed a plurality of times may be different from each other according to process conditions. For example, when operations S120 to S150 are performed twice, the height of the baffle 130 may be substantially the same as the height of the substrate WF in operation S120 performed first, and the height of the baffle 130 may be lower than the height of the substrate WF in operation S120 performed last. In an embodiment, when operations S120 to S150 are performed a plurality of times, the heights of the baffle 130 in operation S140 performed a plurality of times may be different from each other according to process conditions. For example, when operations S120 to S150 are performed twice, the height of the baffle 130 may be lower than the height of the substrate WF in operation S140 performed first, and the height of the baffle 130 may be substantially the same as the height of the substrate WF in operation S140 performed last.

When operations S120 to S150 are performed once or a plurality of times to form a desired pattern on the substrate WF, the substrate WF on which the pattern is formed is discharged out from the process chamber 110. Then, a subsequent process may be performed.

In the substrate treating method according to an embodiment, the height of the baffle 130 functioning as the second electrode is adjusted prior to depositing the sacrificial layer SL on the patterned structure WFP. Also, the height of the baffle 130 functioning as the second electrode is adjusted prior to etching the substrate WF using the sacrificial layer SL. Accordingly, the area of the second electrode varies, and the ratio between the area of the second electrode and the area of the first electrode varies. Consequently, a plasma region PR and a sheath region SR are adjusted, and the straightness of plasma ions may vary. Therefore, when the sacrificial layer SL is deposited on the patterned structure WFP, the profile of the sacrificial layer SL may be adjusted. Accordingly, even when the critical dimension of the patterned structure WFP is small, it is possible to prevent clogging of an opening between neighboring patterned structures WFP due to the sacrificial layer SL. Accordingly, the reliability of an etching process performed using the sacrificial layer SL may be improved, and thus, the quality and yield of semiconductor elements manufactured through the etching process may be enhanced. In addition, when the substrate WF is etched using the sacrificial layer SL, an upper profile of the pattern formed on the substrate WF after etching may be controlled. Accordingly, a more delicate pattern may be formed on the substrate WF.

While the inventive concept has been particularly shown and described with reference to embodiments thereof, it will be understood that various changes in form and details may be made therein without departing from the scope of the following claims.

What is claimed is:

1. A substrate treating apparatus comprising:
a process chamber configured to perform plasma treatment in a treatment space;
a substrate support in a lower portion of the process chamber and configured to support a substrate;
a showerhead in an upper portion of the process chamber and configured to supply a process gas for the plasma treatment toward the substrate; and
a baffle surrounding the substrate support,
wherein the substrate support functions as a first electrode for generating plasma, the showerhead and the baffle function as a second electrode for generating the plasma, the baffle has a variable height, and an area of the second electrode in contact with the treatment space varies as a height of the baffle varies.

2. The substrate treating apparatus of claim 1, wherein radio-frequency (RF) power is applied to the substrate support.

3. The substrate treating apparatus of claim 2, wherein a frequency of the RF power is selected in a range of about 1 Mhz to about 60 Mhz.

4. The substrate treating apparatus of claim 1, comprising a raising/lowering device configured to vertically raise and lower the baffle.

5. The substrate treating apparatus of claim 1, wherein a maximum height of the baffle is equal to a height of the substrate supported by the substrate support.

6. The substrate treating apparatus of claim 1, wherein the showerhead and the baffle comprise a ground electrode.

7. The substrate treating apparatus of claim 1, further comprising a liner on side walls of the process chamber, wherein the liner functions as the second electrode.

8. The substrate treating apparatus of claim 7, wherein the liner comprises a ground electrode.

9. The substrate treating apparatus of claim 1, wherein the plasma treatment comprises plasma etching, plasma-enhanced chemical vapor deposition, or a combination thereof.

10. A substrate treating method comprising:
positioning a substrate having a patterned structure on a substrate support inside a process chamber;
performing first adjustment for adjusting a height of a baffle inside the process chamber;
depositing a sacrificial layer on the patterned structure;
performing second adjustment for adjusting the height of the baffle; and
etching the substrate using the sacrificial layer,
wherein the substrate support functions as a first electrode for generating plasma, the baffle functions as a second electrode for generating the plasma, and an area of the second electrode varies as the height of the baffle varies.

11. The substrate treating method of claim 10, wherein during the first adjustment, the height of the baffle is equal to a height of the substrate positioned on the substrate support.

12. The substrate treating method of claim 10, wherein during the first adjustment, the height of the baffle is lower than a height of the substrate positioned on the substrate support.

13. The substrate treating method of claim 10, wherein the height of the baffle during the first adjustment is higher than the height of the baffle during the second adjustment.

14. The substrate treating method of claim 10, wherein the first adjustment, the depositing, the second adjustment, and the etching are performed a plurality of times.

15. The substrate treating method of claim 14, wherein heights of the baffle are different from each other in the first adjustment performed the plurality of times.

16. The substrate treating method of claim 10, wherein the depositing is performed by using first plasma, the etching is performed by using second plasma, and the first plasma and the second plasma comprise capacitively coupled plasma (CCP).

17. The substrate treating method of claim 10, wherein RF power is applied to the substrate support, and a frequency of the RF power is selected in a range of about 1 Mhz to about 60 Mhz.

18. The substrate treating method of claim 10, wherein the baffle comprises a ground electrode.

19. A substrate treating apparatus comprising:
a process chamber configured to perform plasma treatment in a treatment space;
a substrate support in a lower portion of the process chamber and configured to support a substrate;
a showerhead in an upper portion of the process chamber and configured to supply a process gas for the plasma treatment toward the substrate;
a liner on side walls of the process chamber and configured to protect the side walls of the process chamber; and
a baffle surrounding the substrate support,
wherein the substrate support functions as a first electrode, to which radio-frequency (RF) power having a frequency of 13.56 Mhz is applied, to generate plasma, the showerhead, the baffle, and the liner function as a second electrode, which includes a ground electrode, to generate the plasma, the baffle has a variable height, an area of the second electrode in contact with the treatment space varies as a height of the baffle varies.

20. The substrate treating apparatus of claim 19, wherein a maximum height of the baffle is equal to a height of the substrate supported by the substrate support.
